(19) United States
(12) Patent Application Publication
(10) Pub. No.: US 2024/0178161 A1
(43) Pub. Date: May 30, 2024

(54) ELECTRONIC DEVICE

(71) Applicant: Commissariat à I'Énergie Atomique et aux Énergies Alternatives, Paris (FR)

(72) Inventors: Emilie Bourjot, Grenoble Cedex 9 (FR); Cyrille Laviron, Grenoble Cedex 9 (FR); Jean Charbonnier, Grenoble Cedex 9 (FR); Yann Lamy, Grenoble Cedex 9 (FR)

(73) Assignee: Commissariat à I'Énergie Atomique et aux Énergies Alternatives, Paris (FR)

(21) Appl. No.: 18/522,330

(22) Filed: Nov. 29, 2023

(30) Foreign Application Priority Data
Nov. 30, 2022 (FR) 2212593

(51) Int. Cl. H01L 23/64; H01L 23/00; H01L 23/48; H01L 23/498

(52) U.S. Cl. CPC H01L 23/642; H01L 23/481; H01L 23/49838; H01L 24/08; H01L 2224/08225; H01L 2924/13091

(57) ABSTRACT

An interposer including capacitors having a density greater than 700 nF/mm\hat{ }2. advantageously greater than 1 μF/mm\hat{ }2. the interposer being adapted to being bonded to a chip by hybrid bonding.

### CROSS REFERENCE TO RELATED APPLICATIONS

This application claims priority to French application number 2212593, filed Nov. 30, 2022, the contents of which is incorporated herein by reference in its entirety.

### TECHNICAL FIELD

The present disclosure generally relates to electronic devices and more particularly to devices comprising a chip and an interposer.

### PRIOR ART

Electronic devices often comprise interposers, enabling to form electrical connections between a main chip, bonded to a first side of the interposer, and one or more secondary chips, bonded to a second side of the interposer.

The main chip is, for example, an integrated circuit. The secondary chips for example comprise discrete components or circuits associated with the integrated circuit, for example to enable the integrated circuit to perform functions that cannot be performed by the main chip.

Interposers are generally formed of a layer, for example, made of an electrically-insulating material, conductive vias, and one or more conductive tracks enabling to form routing levels for interconnections. The interposer comprises, for example, contact pads on its first and second sides, the contact pads being coupled to contact pads of the main and secondary chips, for example by solder balls. Such a connection also enables to bond the chips to the interposer.

There is a need to place capacitors in the interposers, to optimize the power supply of the different secondary chips. In particular, there is a need to significantly decrease the parasitic equivalent series inductances (ESL) and equivalent series resistances (ESR), in order to greatly increase the efficiency of the capacitors. Conventionally, the connection of the capacitors, for example, discrete, to an active chip is performed by wire bonding or by means of metal balls having micrometer-range dimensions. These connections themselves generate parasitic inductances (from 5 to 100 pH) and/or resistances (20-100 mOhms). These parasitic inductances or resistances are equivalent to or even exceed the parasitic inductances or resistances of ultra-high-performance capacitors (1 μF/mm2).

### SUMMARY OF THE INVENTION

There is a need to connect very ultra-high-performance capacitors to others without degrading their intrinsic performance with connection parasites.

An embodiment provides an interposer comprising capacitors having a density greater than 700 nF/mm\hat{ }2, advantageously greater than 1 μF/mm\hat{ }2, the interposer being adapted to being bonded to a chip by hybrid bonding.

According to an embodiment, the interposer comprises: a substrate crossed by first conductive vias; a first layer, covering the substrate, having the capacitors located therein; and an interconnection network comprising contact pads adapted to molecular bonding.

According to an embodiment, the first vias have a diameter in the range from 5 μm to 20 μm, advantageously substantially equal to 10 μm, and a height in the range from 50 μm to 200 μm, advantageously substantially equal to 100 μm.

According to an embodiment, the first layer comprises first conductive regions, each first region being in contact with an end of a first via, and being coupled to a contact pad by conductive vias and conductive tracks of the interconnection network.

According to an embodiment, the first regions are laterally surrounded by second insulating regions.

According to an embodiment, the interposer comprises: third regions having the capacitors located therein, fourth insulating regions, each capacitor being laterally surrounded by a fourth insulating region, fifth conductive regions, each fifth region being separated from a third region by a fourth region, and sixth conductive regions, each sixth region coupling a terminal of a capacitor to a fifth region, each fifth region being coupled to a contact pad by second conductive vias and conductive tracks of the interconnection network, another terminal of each capacitor being coupled to a contact pad by second conductive vias and conductive tracks of the interconnection network.

According to an embodiment, each insulating region of the first layer is made of an anodized metal.

According to an embodiment, the capacitors comprise a stack of a second conductive layer, of a third insulating layer, and of a fourth conductive layer, each third region being made of an anodized metal comprising a plurality of cavities crossing said metal, the stack covering the walls of said cavities.

According to an embodiment, the interposer comprises, in at least one area, a density of pads greater than 10\hat{ }3 pads per mm\hat{ }2.

Another embodiment provides a device comprising an interposer such as previously described and at least one first chip bonded to a first surface of the interposer, the at least one first chip being bonded to the first surface by molecular bonding.

According to an embodiment, the forming of the capacitor comprises:—the forming of a fifth layer of a conductive material;—the forming of cavities at the location of the capacitor in the fifth layer by an anodic etching method; and—the conformal forming of a stack of a conductive layer, of an insulating layer, and of a conductive layer at the location of the capacitor.

According to an embodiment, the forming of the insulating regions of the first layer is obtained by a method of anodic etching of a portion of the fifth layer.

According to an embodiment, the method comprises:—the forming of the first vias in the substrate;—the forming of a seventh conductive region extending from the location of each third region to the location of the corresponding fifth region;—the forming of the capacitor, in such a way that a terminal of the capacitor is in contact with the seventh region. According to an embodiment, the fifth layer is made of aluminum.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 schematically shows an embodiment of an electronic device;

FIG. 2 shows a step of a method of manufacturing an embodiment of an electronic device of the type of the device of FIG. 1;

FIG. 3 shows a step of a method of manufacturing an embodiment of an electronic device of the type of the device of FIG. 1;

FIG. 4 shows a step of a method of manufacturing an embodiment of an electronic device of the type of the device of FIG. 1;

FIG. 5 shows a step of a method of manufacturing an embodiment of an electronic device of the type of the device of FIGS. 1; and

FIG. 6 shows a step of a method of manufacturing an electronic device of the type of the device of FIG. 1.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “edge”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

Unless otherwise specified, the terms “insulator” and “conductor” signify “electrically insulating” and “electrically conducting”.

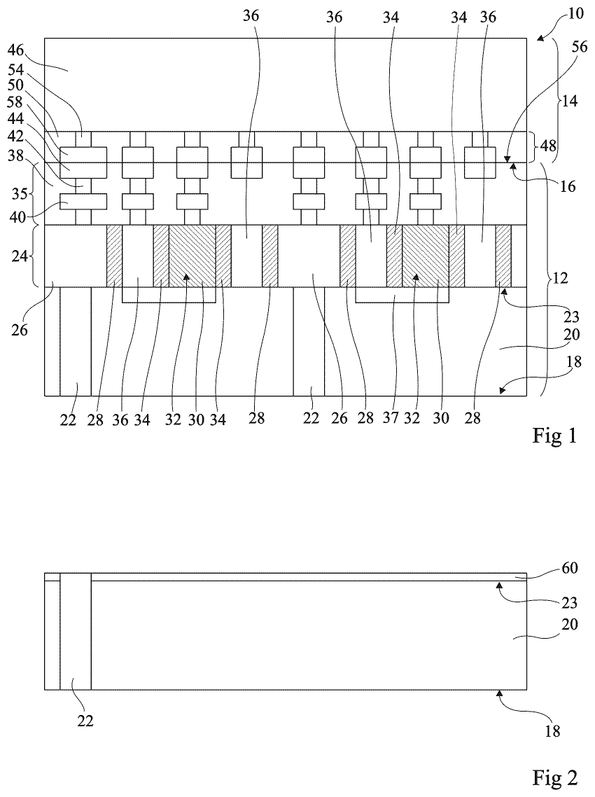

FIG. 1 schematically shows an embodiment of an electronic device 10.

Device 10 comprises an interposer 12. Device 10 further comprises a chip 14 bonded to an upper surface 16 of interposer 12. Although, in FIG. 1, only one chip 14 is shown, device 10 may comprise a plurality of chips 14 bonded the surface 16 of interposer 12. Interposer 12 comprises a lower surface 18, opposite to surface 16. Surface 18 is bonded to a chip, for example a single chip, not shown, or to a ball grid array (BGA) substrate. Surface 18 and the chip, not shown, are for example bonded to each other by solder balls, not shown.

The interposer comprises a layer 20 of insulating material. Layer 20 is for example made of a resin. Layer 20 is for example made of silicon oxide. Layer 20 is for example made of a semiconductor material, for example of silicon. Layer 20 is crossed by through vias 22. Vias 22 are conductive vias. Vias 22 are made of a conductive material, for example of metal. Vias 22 extend from an upper surface 23 of layer 20, to the lower surface of layer 20, corresponding, for example, to surface 18 of the interposer. In other words, vias 22 extend along the entire height of layer 20. Vias 22 have, for example, a diameter in the range from 5 μm to 20 μm, advantageously substantially equal to 10 μm, and a height for example in the range from 50 μm to 200 μm, advantageously substantially equal to 100 μm.

Each via 22 corresponds, for example, to a connection between interposer 12 and the chip, not shown, having the interposer coupled thereto. Interposer 12 comprises, for example, at least as many vias 22 as desired connections between the interposer and the chip, not shown. Interposer 12 comprises, for example, at least as many vias 22 as desired connections between chips 14 and the chip, not shown.

Interposer 12 comprises a layer 24 made of an anodizable conductive material, preferably of metal. Layer 24 is for example made of aluminum, magnesium, or tantalum.

Layer 24 comprises regions 26. Regions 26 are conductive regions. Regions 26 are located opposite vias 22. Regions 26 extend along the entire height of layer 24. Regions 26 thus extend from the upper surface of layer 20 to the upper surface of layer 24. Each region 26 is in contact with an upper end of a via 22, that is, in contact with the end of a via 22 flush with the upper surface of layer 20. Each region 26 enables to continue the electrical link of the via 22 with which region 26 is in contact.

Regions 26 are surrounded by regions 28 of layer 24. Regions 28 are insulating regions. Regions 28 are made of the material of layer 24, for example, of aluminum, which has been anodized, for example, of alumina. Regions 28 are thus porous regions. In other words, regions 28 comprise a plurality of cavities, or nanopores, not shown, extending, for example, along the entire height of region 28.

Layer 24 further comprises regions 30 having capacitors 32 located therein. Each region 30 comprises, for example, a single capacitor 32. Capacitors 32 are high-density capacitors, that is, capacitors having a density greater than 700 nF/mm\hat{ }2, for example greater than 1 μF/mm\hat{ }2.

Regions 30 are, like regions 28, made of the material of layer 24, for example of aluminum which has been anodized, for example of alumina. Regions 30 thus comprise a plurality of cavities, not shown, for example extending along the entire height of region 30. The density of cavities in region 30 is, for example, greater than 40 cavities/μm\hat{ }2.

Capacitors 32 are metal-insulator-metal or MIM capacitors. Each capacitor 32 comprises a stack of layers, not shown in FIG. 1, of an insulating layer located between two conductive layers, preferably made of metal. The layer stack of a capacitor 32 is conformally located on the porous structure of region 30.

A bottom layer of the stack of a capacitor 32, that is, one of the conductive layers, preferably a metal layer, conformally extends over the porous structure, and in particular in the cavities of region 30. The bottom layer of a capacitor 32 covers, preferably entirely, the upper surface of layer 24 in region 30, the side walls of the cavities, and the bottom of the cavities. The bottom layer of a capacitor 32 is thus flush with the lower surface of layer 24.

An intermediate layer of the stack of a capacitor 32, that is, the insulating layer, conformally extends over the bottom layer. The intermediate layer extends in the cavities. The intermediate layer preferably completely covers the bottom layer.

A top layer of the stack of a capacitor 32, that is, the other conductive layer, for example, made of metal, conformally extends over the intermediate layer. The top layer extends in the cavities. The top layer for example fills the cavities. The top layer preferably entirely covers the intermediate layer. The top layer comprises, for example, a planar upper surface extending above the upper surface of the porous structure.

Layer 24 further comprises insulating regions 34 delimiting regions 30. Each region 30 is surrounded by regions 34. Each region 30 is thus laterally insulated from the rest of layer 24. Each region 30 is preferably in direct lateral contact with the regions 34. Thus, regions 30 are preferably not separated from regions 34 by other regions of layer 24. In particular, regions 30 are preferably not separated from regions 34 by regions of the material of layer 24 which has not been anodized and is not porous.

Regions 34 are insulating regions. Regions 34 are made of the material of layer 24, for example, of aluminum which has been anodized, for example of alumina. Regions 34 are thus porous regions. In other words, regions 34 comprise a plurality of cavities, not shown, extending, for example, along the entire height of the region 34.

Layer 24 further comprises conductive regions 36. Regions 36 are regions of the material of layer 24 which have not been anodized and are not porous. Each region 36 extends along the entire height of layer 24. Thus, each region 36 extends from the lower surface of layer 24 to the upper surface of layer 24. Each region 36 is laterally surrounded by regions 28 and/or 34. Preferably, layer 24 comprises at least as many regions 36 as capacitors 32. Preferably, a region 36 is adjacent to each region 30, and regions 30 and 36 are preferably only separated by a region 34. The lower surface of each region 30, that is, the bottom layer of each capacitor 32, is electrically connected to a region 36, preferably the adjacent region 36. Thus, a terminal of the capacitor 32 of each region 30 is coupled, via layer 36, to the upper surface of layer 24.

In the simplified example of FIG. 1, the lower surface of each region 30 is coupled to region 36 by a conductive region 37 located in layer 20. Alternatively, the lower surface of each region 30 may be coupled to region 36 by a conductive region 37, different from the region 37 shown in FIG. 1, extending, in layer 24, under regions 30, 34, and 36, so as to be in contact with the bottom layer of the capacitor 32 of region 30 and with a lower end of the adjacent region 36. Such a layer 37 is for example at least partially, for example entirely, made of the material of regions 26. Such a structure will be described in further detail in relation with FIGS. 2 to 6.

Interposer 12 further comprises an interconnection network 35. In other words, interposer 12 comprises a stack 35 of insulating layers 38, having conductive tracks 40 and conductive vias 42 located therein. Network 35 is located on the upper surface of layer 24. In other words, network 35 is separated from layer 20 by layer 24.

The top layer of stack 35, that is, the layer most distant from layer 24, comprises pads 44 designed to enable the molecular bonding of interposer 12 to chip 14. Pads 44 are flush with the upper surface of stack 35. Pads 44 also enable to electrically couple interposer 12 and chip 14, and thus to electrically couple chip 14 and a chip, not shown, bonded to surface 18 of the interposer. Pads 44 also enable to connect two adjacent chips 14. Preferably, the upper surface of the interposer comprises, over at least part of its surface, a density of pads 44 greater than 10\hat{ }3/mm\hat{ }2.

Each region 26 is connected to a pad 44 by one or a plurality of tracks 40 and one or a plurality of vias. Thus, connections are formed between the upper surface 16 of the interposer and the lower surface 18 of the interposer, via a via 22, a region 26, tracks 40 and vias 42, and a pad 44.

Similarly, each terminal of each capacitor 32, that is, each of the two conductive layers surrounding the insulating layer of each capacitor 32, is connected to a pad 44. Thus, the top layer of each capacitor 32 is connected to a pad 44 via tracks 40 and vias 42. The bottom layer of each capacitor 32 is connected to a pad 44 via a region 37, a region 36, tracks 40, and vias 42.

Chip 14 comprises a main portion 46, for example a semiconductor substrate having electronic components, for example transistors, for example metal oxide semiconductor field-effect transistors (MOSFETs), formed therein.

Chip 14 also comprises an interconnection network 48. In other words, chip 14 comprises a stack 48 of insulating layers 50, having conductive tracks, not shown, and conductive vias 54, located therein. Network 48 is located on the lower surface 56 of portion 46.

The bottom layer of stack 48, that is, the layer most distant from portion 46, comprises pads 58 intended to enable the molecular bonding of interposer 12 to chip 14. Pads 58 are flush with the lower surface of stack 48. Pads 58 further enable to electrically couple interposer 12 and chip 14, and thus to electrically couple chip 14 and a chip, not shown, bonded to surface 18 of the interposer.

Interposer 12 and chip 14 are bonded to each other by molecular bonding. More specifically, surface 56 of chip 14 is bonded by molecular bonding to surface 16 of interposer 12.

FIGS. 2 to 6 show steps, preferably successive, of a method of manufacturing an embodiment of an electronic device of the type of the device of FIG. 1. More specifically, FIGS. 2 to 6 show the forming of a portion of an embodiment of an electronic device of the type of the device of FIG. 1 comprising a via 22, a region 26, a region 28, a region 36, a region 24, two regions 34, a portion of network 35, and a portion of chip 14.

FIG. 2 shows a step of a method of manufacturing an embodiment of an electronic device of the type of the device of FIG. 1.

In this step, an insulating layer 60 is formed on layer 20. More precisely, layer 60 is formed on surface 23 of layer 20. Layer 60 for example covers the entire surface 23 of layer 20. Layer 20 is for example made of silicon. Layer 60 is for example made of silicon oxide.

The step of FIG. 2 also comprises the forming of vias 22. Vias 22 cross layer 60 and layer 20. More precisely, the vias extend from the lower surface 18 of layer 20 to the upper surface of layer 60, that is, the surface of layer 60 most distant from layer 20. For example, the forming of the vias comprises the etching of cavities crossing layer 60 and partially layer 20, the filling of the cavities with the conductive material of vias 22, and the thinning of layer 20 from lower surface 18 in order to expose the lower surfaces of vias 22.

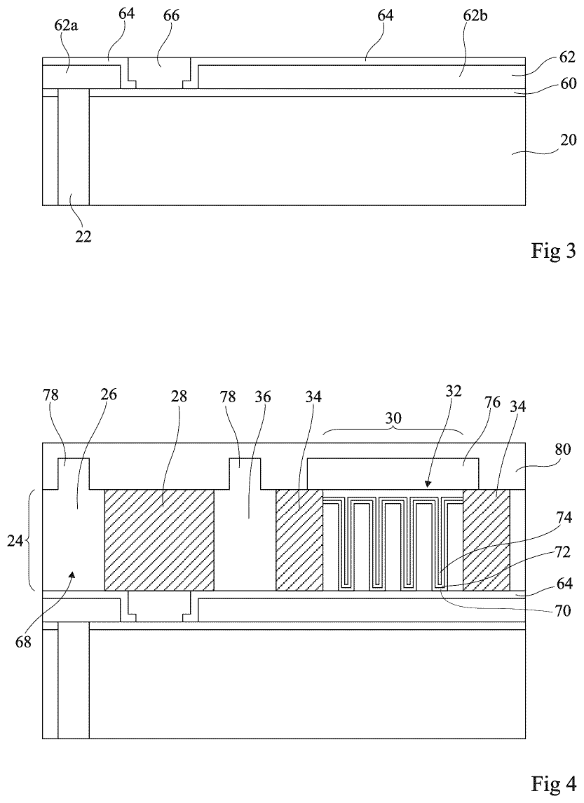

FIG. 3 shows a step of a method of manufacturing an embodiment of an electronic device of the type of the device of FIG. 1.

During this step, a layer 62 made of a conductive material is formed. Layer 62 is for example made of a metal, for example of the material of layer 24, more precisely the material of region 26, for example, made of aluminum. Layer 62 comprises first portions 62a and second portions 62b.

Each portion 62a, only one of which is shown in FIG. 3, is located opposite a via 22 and in contact with said via 22. Each portion 62a thus covers the upper surface of a via 22 and the upper surface of layer 62 located around the upper surface of said via 22.

Each portion 62b, only one of which is shown in FIG. 3, is located opposite the location of a capacitor 32 and of a region 36. Each portion 62b covers, preferably only, and is in contact with layer 60. Each portion 62b corresponds to a region 37, that is, a conductive region of contact with the capacitor terminal closest to layer 20.

Each portion 62a, 62b of layer 62 is covered with a conductive layer 64. Layer 64 is for example made of metal, for example of a stack of layers of titanium nitride, of titanium, and of aluminum, or made of tungsten. The upper surface and the lateral surfaces of each portion 62a, 62b are covered with a layer 64. For example, each layer 64 partially covers the upper surface of layer 60 located between the different portions 62a, 62b. At least a portion of the upper surface of layer 60 located between the different portions 62a, 62b is not covered with a layer 64. The layers 64 covering different portions 62a, 62b are thus not in contact with each other.

Portions 62a, 62b are separated from one another by insulating portions 66, for example made of silicon oxide. Each region 66 is located opposite the location of a region 28.

Portions 66 fill, preferably entirely, cavities located between portions 62a, 62b and between layers 64. Portions 66 thus cover the portions of layers 64 covering the side walls of portions 62a, 62b and the portions of layers 64 covering the upper surface of layer 60. Portions 66 further cover the portions of layer 60 located between layers 64, that is, the portions of layer 60 which are covered neither with portions 62a, 62b nor with layers 64. Portions 62a, 62b are thus electrically insulated from each other.

Preferably, the upper surface of the structure resulting from the step in FIG. 3 is planar. In other words, the upper surfaces of regions 66 and the upper surfaces of the portions of layers 64 located on the upper surfaces of portions 62a, 62b are substantially coplanar.

FIG. 4 shows a step of a method of manufacturing an embodiment of an electronic device of the type of the device of FIG. 1.

During this step, layer 24 is formed. More precisely, a layer 68 made of the material of region 26 is formed on the structure resulting from the step of FIG. 3. In other words, layer 68 covers, preferably entirely, the upper surfaces of regions 66 and the upper surfaces of the portions of layers 64 located on the upper surfaces of portions 62a, 62b.

Layer 68 is made of a conductive material. Layer 68 is a complete, continuous layer. Layer 68 preferably does not comprise cavities during its deposition. Preferably, the lower and upper surfaces of layer 68, that is, the layer closest to layer 20 and the layer most distant from layer 20, are planar and parallel. Layer 68 is for example made of aluminum.

The step of FIG. 4 further comprises the forming of the nanopores in regions 28, 30 and 34 of layer 68. For the sake of clarity, the nanopores of regions 28 and 34 are not shown in FIGS. 4, 5, and 6, and only four nanopores are shown in region 30 in FIGS. 4, 5, and 6.

During the forming of the nanopores in regions 28, 30, and 34, the portions of layer 68 corresponding to regions 28, 30, and 34 are submitted to an anodic etching method, enabling to form a nanostructured metal layer. The anodic etching method is for example preceded by the forming of a mask on layer 68 outside of the locations of regions 28, 30, and 34.

Anodizing, also called anodic etching method, is a wet electrolytic process. The principle is based on the application of a potential difference imposed between two conductive electrodes immersed in an electrolytic solution, which may for example be acidic. In the example of the method of FIGS. 2 to 6, one of the conductive electrodes, for example, the anode, is layer 68. The application of a potential to an electrode induces a growth of alumina on its surface if the electrode is made of aluminum. The dissolving of the aluminum electrode in the acid bath causes the forming of nanopores or cavities in the electrode surface.

The nanopores for example have a diameter in the order of 80 nm and are spaced apart by 50 nm. The nanopore density is, for example, substantially equal to 40 cavities/μm². Further, the anodizing method used enables to obtain nanopores emerging onto layer 64. In other words, nanopores can be considered as nano-cylinders, having a side emerging onto layer 64.

The method of FIG. 4 further comprises the forming of the stack of layers of capacitor 32. More specifically, capacitor 32 comprises a stack of a conductive layer 70, of an insulating layer 72, and of a conductive layer 74 conformally formed in region 30, as described in relation with FIG. 1.

Thus, layer 70, corresponding to the bottom layer of the stack of capacitor 32, preferably a metal layer, conformally extends over the nanopore structure, and in particular inside of the nanopores of region 30. The lower layer of capacitor 32 covers, preferably entirely, the upper surface of layer 24 in region 30, the side walls of the nanopores, and the bottom of the nanopores. The bottom layer of capacitor 32 is thus flush with the lower surface of layer 24. The bottom layer of capacitor 32 is thus electrically coupled to, preferably in contact with, the layer 64 located under capacitor 32.

Layer 72, corresponding to the intermediate layer of the stack of capacitor 32, conformally extends over layer 70. Layer 72 extends in the nanopores. The intermediate layer preferably entirely covers layer 70.

Layer 74, corresponding to the top layer of the stack of capacitor 32, for example made of metal, conformally extends over layer 72. Layer 74 extends in the nanopores. Layer 74 for example fills the nanopores. Layer 74 preferably entirely covers layer 72. Layer 74 for example comprises a planar upper surface extending above the upper surface of the nanopore structure.

The step shown in FIG. 4 preferably involves the forming of a conductive region 76 covering layer 74. Region 76 is for example made of metal. Region 76 preferably entirely covers the upper surface of layer 74. Region 76 for example partially covers the regions 34 surrounding region 30. Region 76 is not in contact with the adjacent regions 36. At this step, region 76 is only electrically coupled to layer 74.

The step of FIG. 4 for example comprises the forming of regions 78, each located, preferably only, on regions 26 and 36. Regions 78 are preferably made of the material of regions 26 and 36, for example, of aluminum. Regions 78 are in contact with the regions 26, 36 on which they rest.

The step of FIG. 4 involves, for example, the forming of an insulating layer 80. Layer 80 preferably entirely covers the structure. Layer 80 thus covers the upper surface of region 28, the upper and lateral surfaces of regions 76 and 78, and the portions of the upper surfaces of regions 26, 34, and 36 which are not covered with regions 76 and 78.

The method of forming capacitor 32 is for example described in further detail in documents WO2015/063420 and EP3680931.

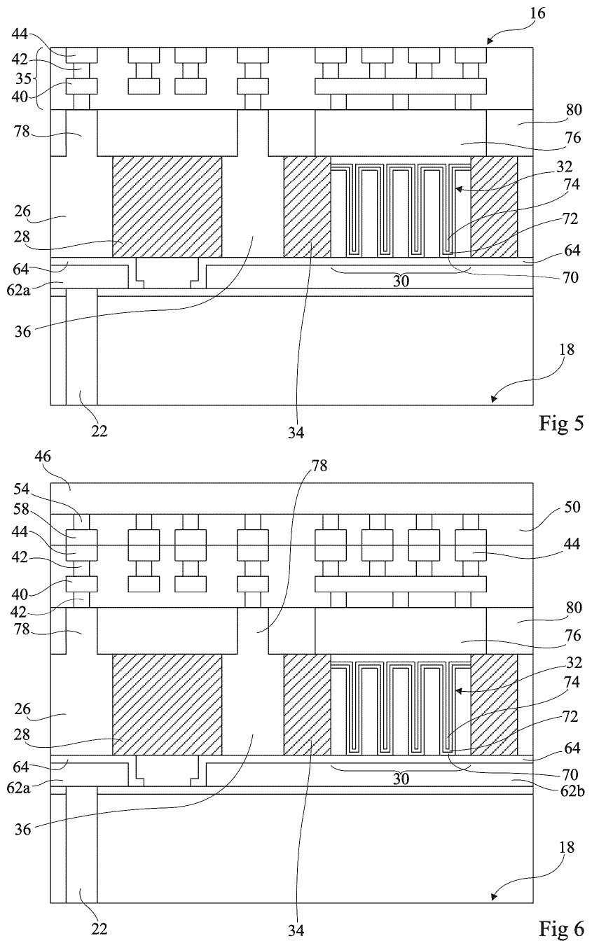

FIG. 5 shows a step of a method of manufacturing an embodiment of an electronic device of the type of the device of FIG. 1.

During this step, interconnection network 35 is formed on the upper surface of the interposer, that is, the surface opposite to surface 18. The forming of the interconnection network is preceded, for example, by the thinning of layer 80 to expose the upper surfaces of regions 76 and 78.

The interconnection network 35 is for example formed by a Damascene process. In other words, the forming of interconnection network 35 comprises, for each layer of the stack, the forming of the insulating layer, the etching of the insulating layer at the locations of vias 42, of tracks 40, and of pads 44, the forming of a conductive layer on the insulating layer to fill the etched locations, and the removal of the portions of the conductive layer located outside of the etched locations.

FIG. 6 shows a step of a method of manufacturing an embodiment of an electronic device of the type of the device of FIG. 1.

During this step, interposer 12 is bonded to a chip 14. Chip 14 is formed, for example, in parallel with the manufacturing of the interposer. The forming of chip 14 comprises the forming of electronic components in a semiconductor substrate 46. The forming of chip 14 further comprises the forming of interconnection network 48, that is, the forming of insulating layers 50, of the conductive tracks, of vias 54, and of pads 58.

Pads 58 are located so as to be in contact with the pads 44 of interposer 12 when chip 14 and the interposer are bonded to each other. The contact between pads 58 and 44 enables to electrically couple chip 14 and interposer 12, and allows the molecular bonding between chip 14 and interposer 12.

The method of manufacturing the device 10 of FIG. 1 further comprises the manufacturing of the main chip, not shown, or the BGA substrate, not shown, and its bonding to surface 18 of the interposer so as to be electrically coupled to the interposer, and more particularly to the lower ends of vias 22.

Electrical links can thus be formed between the lower surface 18 of the interposer and the upper surface 16 of the interposer, that is, between the main chip, not shown, and chip 14, each link being formed by means of a via 22, of a portion 62a, of a layer 64, of a region 26, of a region 78, of tracks 40, of vias 42, and of a pad 44.

Chip 14 is further coupled across capacitor 32. A terminal of capacitor 32,

corresponding to layer 70, is coupled to chip 14 via a layer 64, a portion 62b, a region 36, a region 78, vias 42, tracks 40, and a pad 44. Another terminal of capacitor 32, corresponding to layer 74, is coupled to chip 14 via a region 76, vias 42, tracks 40, a pad 44, and optionally a routing level at the lower surface of the interposer.

An advantage of the described embodiments is the possibility of obtaining high-density capacitive elements in an interposer, which enables to optimize the power transfer.

Another advantage of the described embodiments is that the capacitors are particularly close to the electronic components of the chips bonded to the upper surface of the interposer.

Another advantage of the described embodiments is that the density of interconnections between the interposer and the chips bonded to the upper surface of the interposer is high. Indeed, the use of the pads of an interconnection network to form connections with the chips and to bond the chips and the interposer by molecular bonding enables to add the links corresponding to the capacitors without increasing the size of the interposer.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

What is claimed is:

1. Interposer comprising capacitors having a density greater than 700 nF/mm\hat{ }2, advantageously greater than 1 μF/mm\hat{ }2, the interposer being adapted to being bonded to a chip by hybrid bonding.

2. Interposer according to claim 1, wherein the interposer comprises:
a substrate crossed by first conductive vias;
a first layer, covering the substrate, having the capacitors located therein; and
an interconnection network comprising contact pads adapted to molecular bonding.

3. Interposer according to claim 1, wherein the first vias have a diameter in the range from 5 μm to 20 μm, advantageously substantially equal to 10 μm, and a height in the range from 50 μm to 200 μm, advantageously substantially equal to 100 μm.

4. Interposer according to claim 1, wherein the first layer comprises first conductive regions, each first region being in contact with an end of a first via, and being coupled to a contact pad by conductive vias and conductive tracks of the interconnection network.

5. Interposer according to claim 4, wherein the first regions are laterally surrounded by second insulating regions.

6. Interposer according to claim 1, wherein the interposer comprises:
third regions having the capacitors located therein,
fourth insulating regions, each capacitor being laterally surrounded by a fourth insulating region,
fifth conductive regions, each fifth region being separated from one of the third regions by one of the fourth regions, and
sixth conductive regions, each sixth region coupling a terminal of one of the capacitors to a fifth region, each fifth region being coupled to a contact pad by second conductive vias and conductive tracks of the interconnection network, another terminal of each capacitor being coupled to a contact pad by second conductive vias and conductive tracks of the interconnection network.

7. An interposer according to claim 5, wherein each insulating region of the first layer is made of an anodized metal.

8. Interposer according to claim 6, wherein the capacitors comprise a stack of a second conductive layer, of a third insulating layer, of a fourth conductive layer, each third region being made of an anodized metal comprising a plurality of cavities crossing said metal, the stack covering the walls of said cavities.

9. Interposer according to claim 1, wherein the interposer comprises, in at least one area, a density of pads greater than 10\hat{ }3 pads per mm\hat{ }2.

10. Device comprising an interposer such as described according to claim 1 and at least one first chip bonded to a first surface of the interposer, the at least one first chip being bonded to the first surface by molecular bonding.

11. Method of manufacturing an interposer according to claim 1, wherein the forming of each capacitor comprises:
the forming of a fifth layer of a conductive material;
the forming of cavities at the location of the capacitor in the fifth layer by an anodic etching method; and
the conformal forming of a stack of a conductive layer, of an insulating layer, and of a conductive layer at the location of the capacitor.

12. Method according to claim 11, wherein the forming of the insulating regions of the first layer is obtained by a method of anodic etching of a portion of the fifth layer.

13. Method according to claim 11, wherein the interposer comprises
a substrate crossed by first conductive vias;
a first layer, covering the substrate, having the capacitors located therein;
an interconnection network comprising contact pads adapted to molecular bonding;
third regions having the capacitors located therein;
fourth insulating regions, each capacitor being laterally surrounded by a fourth insulating region;
fifth conductive regions, each fifth region being separated from one of the third regions by one of the fourth regions;
sixth conductive regions, each sixth region coupling a terminal of one of the capacitors to a fifth region, each fifth region being coupled to a contact pad by second conductive vias and conductive tracks of the interconnection network, another terminal of each capacitor being coupled to a contact pad by second conductive vias and conductive tracks of the interconnection network;
the method comprises:
the forming of the first vias in the substrate;
the forming of a seventh conductive region extending from the location of each third region to the location of the corresponding fifth region;
the forming of each capacitor, in such a way that a terminal of each capacitor is in contact with the seventh region.

14. Method according to claim 11, wherein the fifth layer is made of aluminum.
